(19) United States
(12) Patent Application Publication
(10) Pub. No.: US 2026/0343882 A1
(43) Pub. Date: Oct. 29, 2026

(54) METHOD OF MANUFACTURING SEMICONDUCTOR DEVICE

(71) Applicant: SK hynix Inc., Gyeonggi-do (KR)

(72) Inventor: Sang Bum LEE, Gyeonggi-do (KR)

(21) Appl. No.: 19/315,858

(22) Filed: Sep. 2, 2025

(30) Foreign Application Priority Data
Apr. 28, 2025 (KR) 10-2025-0055564

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A method of manufacturing a semiconductor device includes: forming a first stack that includes first insulating layers and first sacrificial layers that are alternately stacked, and the first sacrificial layers each having a first etch rate; forming a second stack on the first stack, the second stack including second insulating layers and second sacrificial layers that are alternately stacked, and the second sacrificial layers each having a second etch rate lower than the first etch rate; forming a first opening extending through the first stack and the second stack; forming second openings that are connected to the first opening by etching the first sacrificial layers; forming a first barrier pattern that covers the second stack; forming second barrier patterns in the second openings, which cover the first sacrificial layers; and etching the first insulating layers using the first barrier pattern and the second barrier patterns as etching barriers.

### CROSS-REFERENCE TO RELATED APPLICATION

This application claims priority under 35 U.S.C. §119 to Korean Patent Application No. 10-2025-0055564 filed on Apr. 28, 2025, which is incorporated herein by reference in its entirety.

### BACKGROUND

Embodiments of the present disclosure relate generally to an electronic device, and, more particularly, to a semiconductor device and a method of manufacturing the semiconductor device.

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, to improve the operational reliability of such a semiconductor device, various structures and manufacturing methods have been developed.

In an embodiment of the present disclosure, a method of manufacturing a semiconductor device may include forming a first stack including first insulating layers and first sacrificial layers that are alternately stacked, each of the first sacrificial layers having a first etch rate; forming a second stack on the first stack, the second stack including second insulating layers and second sacrificial layers that are alternately stacked, each of the second sacrificial layers having a second etch rate lower than the first etch rate; forming a first opening extending through the first stack and the second stack; forming second openings by etching the first sacrificial layers through the first opening, the second openings being connected to the first opening; forming a first barrier pattern in the first opening, the first barrier pattern covering the second stack; forming second barrier patterns in the second openings, the second barrier patterns covering the first sacrificial layers; and etching the first insulating layers using the first barrier pattern and the second barrier patterns as etching barriers.

In an embodiment of the present disclosure, a method of manufacturing a semiconductor device may include forming a first stack including first insulating layers and first sacrificial layers that are alternately stacked; forming a second stack on the first stack, the second stack including second insulating layers and second sacrificial layers that are alternately stacked; forming a first opening extending through the first stack and the second stack; forming second openings by etching the first sacrificial layers through the first opening, the second openings being connected to the first opening; forming a barrier layer along surfaces of the first stack and the second stack exposed through the first opening and the second openings, the barrier layer having a first thickness on the first insulating layers and a second thickness on the second insulating layers wherein the second thickness is greater (or thicker) than the first thickness; forming a first barrier pattern by etching the barrier layer, the first barrier pattern covering the second stack; forming second barrier patterns in the second openings by etching the barrier layer; and etching the first insulating layers using the first barrier pattern and the second barrier patterns as etching barriers.

### BRIEF DESCRIPTION OF THE DRAWINGS

FIG. 1 is a diagram illustrating the structure of a semiconductor device in accordance with an embodiment of the present disclosure.

FIG. 2 is a diagram illustrating the structure of a semiconductor device in accordance with an embodiment of the present disclosure.

FIG. 3 is a diagram illustrating the structure of a semiconductor device in accordance with an embodiment of the present disclosure.

FIG. 4 is a diagram illustrating the structure of a semiconductor device in accordance with an embodiment of the present disclosure.

FIGS. 5A to 5H are simplified schematic diagrams describing a method of manufacturing a semiconductor device in accordance with an embodiment of the present disclosure.

FIGS. 6A to 6K are simplified schematic diagrams describing a method of manufacturing a semiconductor device in accordance with an embodiment of the present disclosure.

FIG. 7 is a configuration diagram of a semiconductor device in accordance with an embodiment of the present disclosure.

FIG. 8 is a configuration diagram of a semiconductor device in accordance with an embodiment of the present disclosure.

### DETAILED DESCRIPTION

Various embodiments are directed to a semiconductor device having a stable structure and improved characteristics and a method of manufacturing the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical features and scope of the present disclosure will be described with reference to the accompanying drawings.

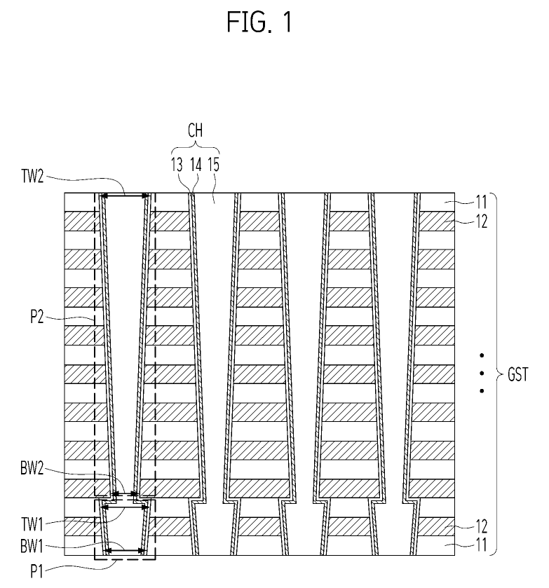

FIG. 1 is a diagram illustrating the structure of a semiconductor device in accordance with an embodiment of the present disclosure.

Referring to FIG. 1, the semiconductor device may include a gate structure GST and a channel structure CH. The gate structure GST may include insulating layers 11 and conductive layers 12 that are alternately stacked. The conductive layers 12 may be gate lines such as word lines, source select lines, or drain select lines. The conductive layers 12 may each include a conductive material such as, for example, polysilicon tungsten (W), or molybdenum (Mo). For example, at least one conductive layer 12 located at the lowermost portion may be a source select line, at least one conductive layer 12 located at the uppermost portion may be a drain select line, and the remaining conductive layers 12 may be word lines. The insulating layers 11 may insulate the stacked conductive layers 12 from each other. Each insulating layer 11 may include an insulating material such as, for example, an oxide nitride, or air gap.

The channel structure CH may extend through the gate structure GST. The channel structure CH may include a memory layer 13, a channel layer 14, and an insulating core 15. The memory layer 13 may surround sidewalls of the channel layer 14, and the insulating core 15 may be located in the channel layer b. The memory layer 13 may include at least one of a tunneling layer, a data storage layer, and a blocking layer. The tunneling layer may surround the sidewalls of the channel layer 14, the data storage layer may surround the tunneling layer, and the blocking layer may surround the data storage layer. For example, the data storage layer may include a floating gate, polysilicon, nitride, a charge trap material, a variable resistance material, or the like. The blocking layer may include a high-k material, and may be a single layer or a multilayer layer.

A source select transistor, memory cells, or a drain select transistor may be located in regions where the channel structure CH and the conductive layers 12 intersect each other. For example, at least one source select transistor, a plurality of memory cells, and at least one drain select transistor may be stacked along the channel structure CH. At least one source select transistor, a plurality of memory cells, and at least one drain select transistor that share the channel structure CH with each other may constitute one memory string.

The channel structure CH may include a first portion P1 and a second portion P2. In a cross sectional view, as illustrated in FIG. 1, the first portion P1 and the second portion P2 may each have a uniform width or a width changing gradually depending on a level. The level as this term is used herein refers to a position along a vertical direction (also referred to as the stacking direction). As illustrated in the example of FIG. 1, each of the first portion P1 and the second portion P2 may have a tapered shape or a bowing shape, and a step may exist at a portion where the first portion P1 and the second portion P2 are connected to each other. At the portion where the first portion P1 and the second portion P2 are connected to each other, a top width TW1 of the first portion P1 may be greater than a bottom width BW2 of the second portion P2. In addition, a bottom width BW1 of the first portion P1 may be greater than the bottom width BW2 of the second portion P2. The top width TW1 of the first portion P1 may be the same or substantially the same with a top width of the second portion P2.

According to the structure described above, the channel structure CH may include the first portion P1 and the second portion P2, and the bottom width BW1 of the first portion P1 may be greater than the bottom width BW2 of the second portion P2. Accordingly, as the bottom width BW1 of the first portion P1 increases, a channel width of a source select transistor located to correspond to the first portion P1 may be increased, and a cell current may be improved.

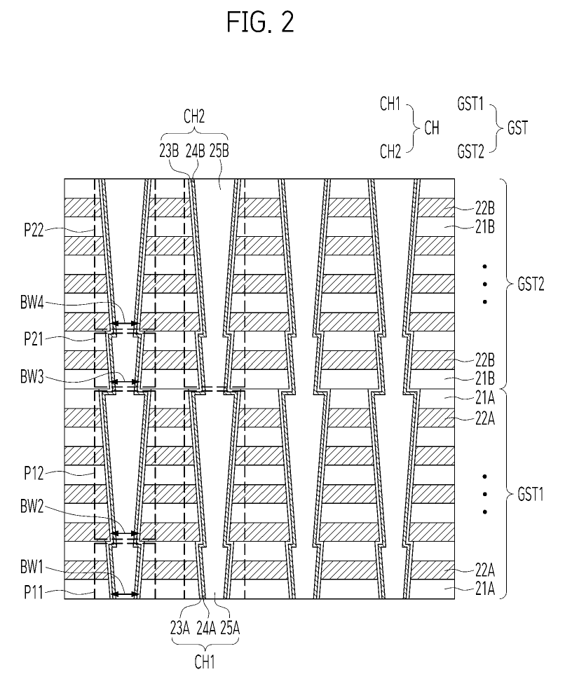

FIG. 2 is a diagram illustrating the structure of a semiconductor device in accordance with an embodiment of the present disclosure.

Referring to FIG. 2, the semiconductor device may include a gate structure GST and a channel structure CH. The gate structure GST may include a first gate structure GST1 and a second gate structure GST2. The first gate structure GST1 may include first insulating layers 21A and first conductive layers 22A that are alternately stacked, and the second gate structure GST2 may include second insulating layers 21B and second conductive layers 22B that are alternately stacked. The first and second conductive layers 22A and 22B may be gate lines such as word lines, source select lines, or drain select lines. The first and second conductive layers 22A and 22B may each include a conductive material such as, for example, polysilicon tungsten (W), or molybdenum (Mo). For example, at least one first and second conductive layers 22A and 22B located at the lowermost portions may be source select lines, at least one first and second conductive layers 22A and 22B located at the uppermost portions may be drain select lines, and the remaining first and second conductive layers 22A and 22B may be word lines. The first and second insulating layers 21A and 21B are used to insulate the stacked first and second conductive layers 22A and 22B from each other, and may each include an insulating material such as, for example, an oxide nitride, or air gap. For example, thicknesses of the uppermost first insulating layer 21A of the first gate structure GST1 and the lowermost second insulating layer 21B of the second gate structure GST2 may be different from thicknesses of the remaining first and second insulating layers 21A and 21B. The thicknesses of the uppermost first insulating layer 21A of the first gate structure GST1 and the lowermost second insulating layer 21B of the second gate structure GST2 may be smaller or greater than the thicknesses of the remaining first and second insulating layers 21A and 21B.

The channel structure CH may include a first channel structure CH1 and a second channel structure CH2. The first channel structure CH1 may extend through the first gate structure GST1. The first channel structure CH1 may include a memory layer 23A, a channel layer 24A, and an insulating core 25A. The first channel structure CH1 may include a first portion P11 and a second portion P12. In a cross section, the first portion P11 and the second portion P12 may each have a uniform width or a width changed depending on a level. In this case, the level may be a level along the vertical direction or the stacking direction. For example, each of the first portion P11 and the second portion P12 may have a tapered shape or a bowing shape, and a step may exist at a portion where the first portion P11 and the second portion P12 are connected to each other. A bottom width BW1 of the first portion P11 may be greater than a bottom width BW2 of the second portion P12.

The second channel structure CH2 may extend through the second gate structure GST2. The second channel structure CH2 may include a memory layer 23B, a channel layer 24B, and an insulating core 25A. The second channel structure CH2 may include a first portion P21 and a second portion P22. In a cross section, the first portion P21 and the second portion P22 may each have a uniform width or a width changed depending on a level. In this case, the level may be a level along the vertical direction or the stacking direction. For example, each of the first portion P21 and the second portion P22 may have a tapered shape or a bowing shape, and a step may exist at a portion where the first portion P21 and the second portion P22 are connected to each other. A bottom width BW3 of the first portion P21 may be greater than a bottom width BW4 of the second portion P22.

According to the structure described above, the first channel structure CH1 may include the first portion P11 and the second portion P12, and the bottom width BW1 of the first portion P11 may be greater than the bottom width BW2 of the second portion P12. Accordingly, a channel width of a source select transistor may be increased, and a cell current may be improved. In addition, the second channel structure CH2 may include the first portion P21 and the second portion P22, and the bottom width BW3 of the first portion P21 may be greater than the bottom width BW4 of the second portion P22. Accordingly, an alignment margin between the first channel structure CH1 and the second channel structure CH2 may be increased.

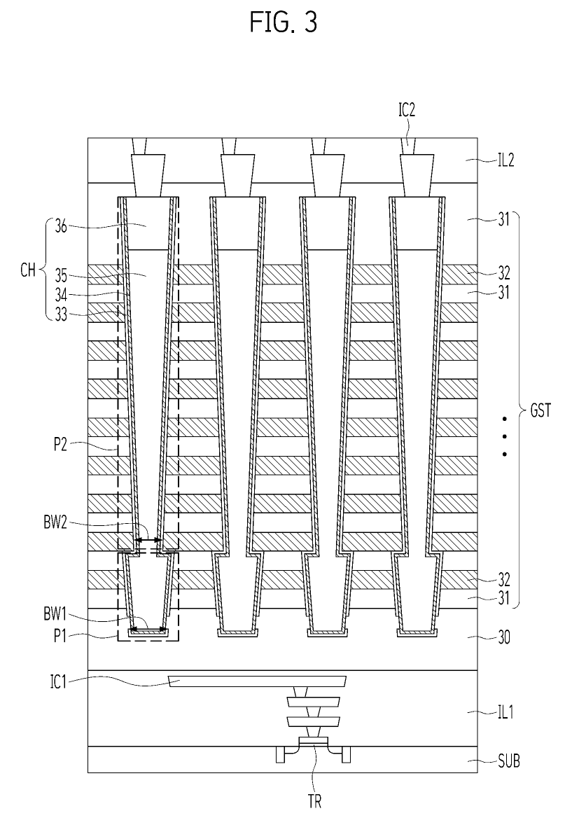

FIG. 3 is a diagram illustrating the structure of a semiconductor device in accordance with an embodiment of the present disclosure. Hereinafter, content overlapping with previously described content may be omitted.

Referring to FIG. 3, the semiconductor device may include a substrate SUB, a transistor TR, a first interconnection structure IC1, a first interlayer insulating layer IL1, a source structure 30, a gate structure GST, a channel structure CH, a second interconnection structure IC2, and a second interlayer insulating layer IL2. A peripheral circuit may be located below a memory cell array.

The transistor TR may be located on the substrate SUB. The transistor TR may belong to the peripheral circuit. For example, the peripheral circuit may include a row decoder, a page buffer, an input/output circuit, a logic circuit, and the like. The first interconnection structure IC1 may be located in the first interlayer insulating layer IL1, and may be electrically connected to the peripheral circuit. The first interconnection structure IC1 may include a via, a wiring line, and the like.

The source structure 30 may be located on the first interlayer insulating layer IL1, and the gate structure GST may be located on the source structure 30. The gate structure GST may include insulating layers 31 and conductive layers 32 that are alternately stacked. The channel structure CH may extend through the gate structure GST, and may be connected to the source structure 30.

The channel structure CH may include a memory layer 33, a channel layer 34, an insulating core 35, and a capping layer 36. The capping layer 36 may be used as a channel pad for connecting the channel layer 34 and a bit line to each other. For example, the capping layer 36 may include a conductive material such as polysilicon or metal. The channel structure CH may include a first portion P1 and a second portion P2, and a bottom width BW1 of the first portion P1 may be greater (or wider) than a bottom width BW2 of the second portion P2.

The second interconnection structure IC2 may be located in the second interlayer insulating layer IL2, and may be connected to the channel structure CH or the like. The second interconnection structure IC2 may include a via, a wiring line, and the like.

According to the structure described above, by locating the peripheral circuit below the memory cell array, it is possible to increase the degree of integration of the semiconductor device. In addition, as the bottom width BW1 of the first portion P1 increases, a channel width of a source select transistor located to correspond to the first portion P1 may be increased, and a cell current may be improved.

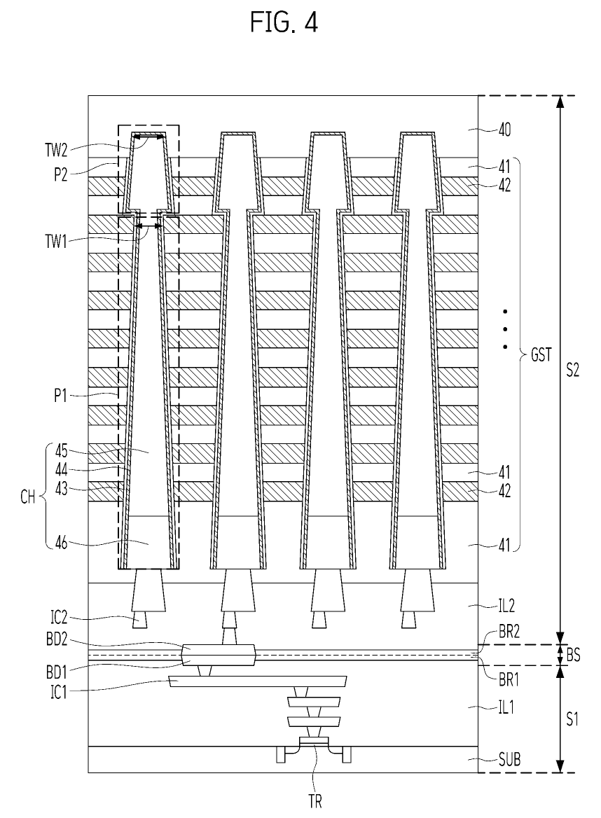

FIG. 4 is a diagram illustrating the structure of a semiconductor device in accordance with an embodiment of the present disclosure. Hereinafter, content overlapping with previously described content may be omitted.

Referring to FIG. 4, the semiconductor device may include a first semiconductor structure S1, a second semiconductor structure S2, and a bonding structure BS. The first semiconductor structure S1 may include a peripheral circuit, and the second semiconductor structure S2 may include a memory cell array.

The first semiconductor structure S1 may include a substrate SUB, a transistor TR, a first interlayer insulating layer IL1, and a first interconnection structure IC1. The transistor TR may belong to the peripheral circuit. The first interconnection structure IC1 may be located in the first interlayer insulating layer IL1, and may include a via, a wiring line, and the like. The first interconnection structure IC1 may be electrically connected to the peripheral circuit.

The second semiconductor structure S2 may include a source structure 40, a gate structure GST, a channel structure CH, a second interlayer insulating layer IL2, and a second interconnection structure IC2. The gate structure GST may include insulating layers 41 and conductive layers 42 that are alternately stacked. The source structure 40 may be located above or below the gate structure GST. The channel structure CH may extend through the gate structure GST, and may be connected to the source structure 40. For example, the channel structure CH may extend into the source structure 40. The channel structure CH may include a memory layer 43, a channel layer 44, an insulating core 45, and a capping layer 46. The channel structure CH may include a first portion P1 and a second portion P2. A top width TW2 of the second portion P2 may be greater than a top width TW1 of the first portion P1.

The bonding structure BS may be located between the first semiconductor structure S1 and the second semiconductor structure S2. The first semiconductor structure S1 and the second semiconductor structure S2 may be manufactured separately, and may be electrically connected to each other by the bonding structure BS. The memory cell array and the peripheral circuit including the transistor TR may be electrically connected to each other through the bonding structure BS.

The bonding structure BS may include a first bonding layer BR1, a second bonding layer BR2, a first bonding pad BD1, and a second bonding pad BD2. The first bonding layer BR1 and the second bonding layer BR2 may be in contact with each other. Also, the first bonding pad BD1 and the second bonding pad BD2 may be in contact with each other. The first bonding layer BR1 and the second bonding layer BR2 may each include, for example, SiCN, tetra ethyl ortho silicate (TEOS), or the like. The first bonding pad BD1 may be electrically connected to the first interconnection structure IC1 while the second bonding pad BD2 may be electrically connected to the second interconnection structure IC2. The memory cell array and the peripheral circuit may be electrically connected to each other through the first bonding pad BD1 and the second bonding pad BD2.

According to the structure described above, the first and second semiconductor structures S1 and S2 may be bonded to each other in a vertical direction, and it is thus possible to increase the degree of integration of the semiconductor device. In addition, as the top width TW2 of the second portion P2 increases, a channel width of a source select transistor located to correspond to the second portion P2 may be increased, and a cell current may be improved. In other words, as the TW2 increases, the channel width of the source select transistor also increases. The channel increased width of the channel means that more carriers can pass through at once, which reduces resistance and enhances conductivity.

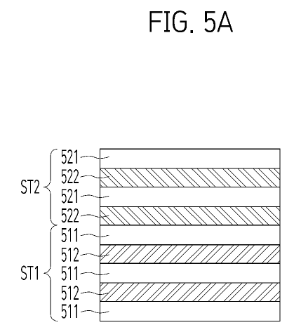

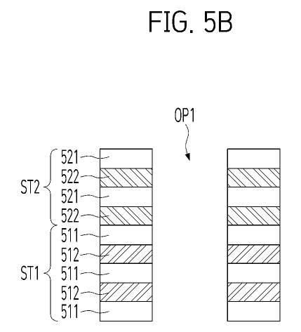

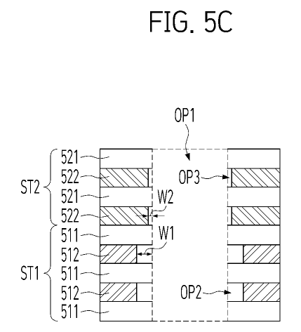

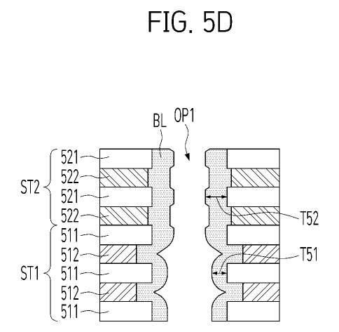

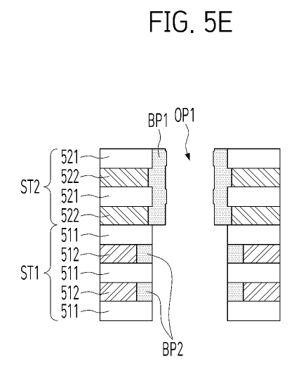

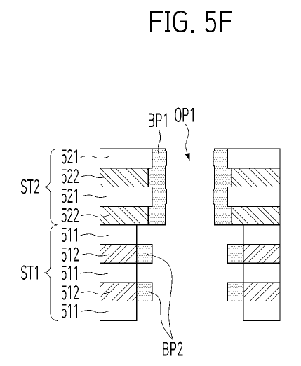

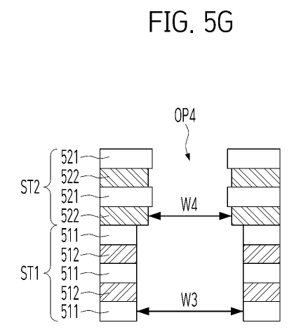

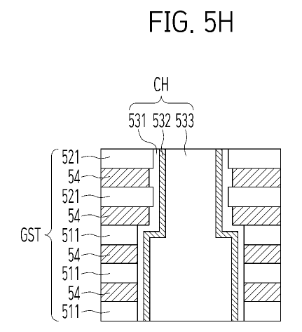

FIGS. 5A to 5H are simplified schematic diagrams describing a method of manufacturing a semiconductor device in accordance with an embodiment of the present disclosure. Hereinafter, content overlapping with previously described content may be omitted.

Referring to FIG. 5A, a first stack ST1 may be formed including first insulating layers 511 and first sacrificial layers 512 that are alternately stacked. The first sacrificial layers 512 may be used to form gate lines. The first sacrificial layers 512 may each include a material having a high etching selectivity with respect to the first insulating layers 511. The first insulating layer 511 located at the uppermost portion of the first stack ST1 may have a greater thickness than the other first insulating layers 511. For example, the first sacrificial layers 512 may each include nitride, and the first insulating layers 511 may each include oxide.

Subsequently, a second stack ST2 may be formed on the first stack ST1. The second stack ST2 may include second insulating layers 521 and second sacrificial layers 522 that are alternately stacked. The second sacrificial layers 522 may each include a material having a high etching selectivity with respect to the second insulating layers 521. For example, the second sacrificial layers 522 may each include nitride, and the second insulating layers 521 may each include oxide.

The first sacrificial layers 512 may each have a first etch rate, and the second sacrificial layers 522 may each have a second etch rate different from the first etch rate. The second etch rate may be lower than the first etch rate. For example, a difference in etch rate between the first sacrificial layers 512 and the second sacrificial layers 522 may be due to a difference in density between the first sacrificial layers 512 and the second sacrificial layers 522. The first sacrificial layers 512 may each have a first density, and the second sacrificial layers 522 may each have a second density different from the first density. The first density may be lower than the second density.

Densities of the first sacrificial layers 512 and the second sacrificial layers 522 may be determined according to a process condition. The first sacrificial layers 512 may be formed at a first pressure, and the second sacrificial layers 522 may be formed at a second pressure different from the first pressure. The first pressure may be higher than the second pressure, and the first density of the first sacrificial layers 512 may be lower than the second density of the second sacrificial layers 522. The flow rates of silane (SiH₄) gas and ammonia (NH₃) gas used during the formation of the first sacrificial layers 512 and the second sacrificial layers 522 may differ. Specifically, the flow rates of silane and ammonia for the first sacrificial layers 512 may be higher than the corresponding flow rates used for the second sacrificial layers 522. Flow rates of the silane gas and the ammonia gas used when forming the first sacrificial layers 512 and flow rates of silane gas and the ammonia gas used when forming the second sacrificial layers 522 may be different from each other. The flow rates of the SiH₄ gas and the NH₃ gas used when forming the first sacrificial layers 512 may be greater than the flow rates of the SiH₄ gas and the NH₃ gas used when forming the second sacrificial layers 522. In such a case, a content of hydrogen in the first sacrificial layers 512 may be higher than a content of hydrogen in the second sacrificial layers 522, and the density of the first sacrificial layers 512 may be lower than the density of the second sacrificial layers 522.

Referring to FIG. 5B, a first opening OP1 extending through the first stack ST1 and the second stack ST2 may be formed. The first opening OP1 may extend in the stacking direction or the vertical direction. The first opening OP1 is used as a passage for forming second openings OP2 and third openings OP3, and may be a channel hole in which a channel structure is formed in a subsequent process. In a plan view, the first opening OP1 may have a circular shape, an elliptical shape, a polygonal shape, or the like.

Referring to FIG. 5C, the second openings OP2 may be formed by etching the first sacrificial layers 512 through the first opening OP1. More specifically, the second openings OP2 may be formed by etching the edge regions of the first sacrificial layers 512 which are exposed to the first opening OP1. The second openings OP2 may be connected to the first opening OP1, and may surround the first opening OP1. Third openings OP3 may also be formed by etching the second sacrificial layers 522 through the first opening OP1. The third openings OP3 may be connected to the first opening OP1, and may surround the first opening OP1.

The first and second sacrificial layers 512 and 522 may each have a high etching selectivity with respect to the first and second insulating layers 511 and 521. Accordingly, when the second openings OP2 are formed, the third openings OP3 may be formed. However, shapes of the second openings OP2 and the third openings OP3 may be different from each other due to the difference in the etch rate between the first sacrificial layers 512 and the second sacrificial layers 522. An etching speed of the first sacrificial layers 512 may be higher (or faster) than that of the second sacrificial layers 522, and a first width W1 of the second openings OP2 may be greater than a second width W2 of the third openings OP3.

Referring to FIG. 5D, a barrier layer BL may be formed in the first opening OP1, the second openings OP2, and the third openings OP3. The barrier layer BL may be formed along the exposed surfaces of the first stack ST1 and the second stack ST2. The barrier layer BL may include a material having a high etching selectivity with respect to the first insulating layers 511 and the second insulating layers 512. For example, the barrier layer BL may include polysilicon.

A first thickness T51 of the barrier layer BL formed on sidewalls of the first insulating layers 511 may be different from a second thickness T52 of the barrier layer BL formed on sidewalls of the second insulating layers 521. Deposition environments of an upper portion and a lower portion of the first opening OP1 may be different from each other, and a thickness difference may occur according to a difference in the deposition environment. A deposition speed of the upper portion may be faster than that of the lower portion, and the second thickness T52 may be greater than the first thickness T51.

Referring to FIG. 5E, a first barrier pattern BP1 covering the second stack ST2 may be formed in the first opening OP1 by etching the barrier layer BL. In addition, second barrier patterns BP2 covering the first sacrificial layers 512 may be formed in the second openings OP2 by etching the barrier layer BL. The first barrier pattern BP1 and the second barrier patterns BP2 may be simultaneously formed by etching the barrier layer BL. Because the second thickness T52 is greater than the first thickness T51, the first barrier pattern BP1 may be formed in a spacer shape along sidewalls of the second stack ST2. The second barrier patterns BP2 may be formed in the second openings OP2, and may be separated from each other. Sidewalls of the second barrier patterns BP2 may be aligned with the sidewalls of the first insulating layers 511. Through this, the first insulating layers 511 may be exposed in the first opening OP1.

Referring to FIG. 5F, the first insulating layers 511 exposed in the first opening OP1 may be etched using the first barrier pattern BP1 and the second barrier patterns BP2 as etching barriers. In this case, the first insulating layers 511 may be etched so that the sidewalls of the first insulating layers 511 are aligned with sidewalls of the first sacrificial layers 512. The second barrier patterns BP2 may protrude toward the first opening OP1 compared to the first insulating layers 511 and the first sacrificial layers 512. In other words, the second barrier patterns BP2 may extend more toward the first opening OP1 compared to the first insulating layers 511 and the first sacrificial layers 512.

Referring to FIG. 5G, the first barrier pattern BP1 and the second barrier patterns BP2 may be removed through the first opening OP1. Specifically, a fourth opening OP4 may be formed by selectively etching the first and second barrier patterns BP1 and BP2 under the condition that etching selectivities of the first and second barrier patterns BP1 and BP2 with respect to the first and second stacks ST1 and ST2 are high. Within the fourth opening OP4, a third width W3 corresponding to the lowermost portion of the first stack ST1 may be greater.

than a fourth width W4 corresponding to the lowermost portion of the second stack ST2.

Referring to FIG. 5H, a channel structure CH may be formed in the fourth opening OP4. A memory layer 531, a channel layer 532, and an insulating core 533 may be formed in the fourth opening OP4. For example, a blocking layer may be formed in the fourth opening OP4, and a data storage layer and a tunneling layer may be formed on the blocking layer. The channel layer 532 may be formed on the tunneling layer, and an inner portion of the channel layer 532 may be filled with the insulating core 533.

Subsequently, the first sacrificial layers 512 and the second sacrificial layers 522 may be replaced with conductive layers 54. For example, a slit extending through the first stack ST1 and the second stack ST2 may be formed and the first sacrificial layers 512 and the second sacrificial layers 522 may be removed through the slit. Subsequently, the conductive layers 54 may be formed in the regions where the first sacrificial layers 512 and the second sacrificial layers 522 are removed. Through this, a gate structure GST including the conductive layers 54 and the first insulating layers 511 that are alternately stacked and the conductive layers 54 and the second insulating layers 521 that are alternately stacked may be formed. For example, the conductive layers 54 may each include a conductive material such as, for example, polysilicon tungsten (W), or molybdenum (Mo).

When the first and second sacrificial layers 512 and 522 are removed through the slit, the first and second sacrificial layers 512 and 522 may be etched so that sidewalls of the channel structure CH is exposed. Because the etching speed of the second sacrificial layers 522 is lower (or slower) than that of the first sacrificial layers 512, an etching condition may be set so that the second sacrificial layers 522 may be sufficiently etched.

According to the method described above, the fourth opening OP4 whose bottom width is expanded may be formed using the first and second sacrificial layers 512 and 522 having different etch rates, the first barrier pattern BP1, and the second barrier patterns BP2. In addition, the channel structure CH whose bottom width is expanded may be formed in the fourth opening OP4. Accordingly, a channel width of a source select transistor may be increased, and a cell current may be improved.

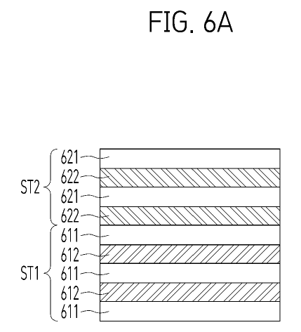

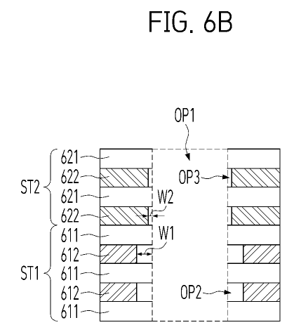

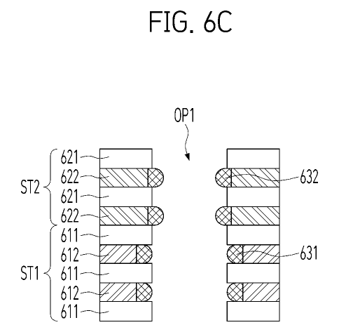

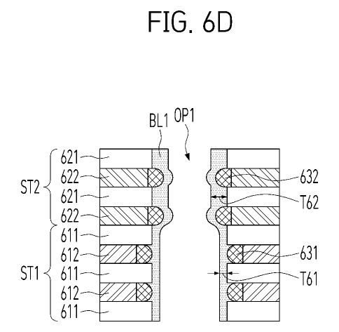

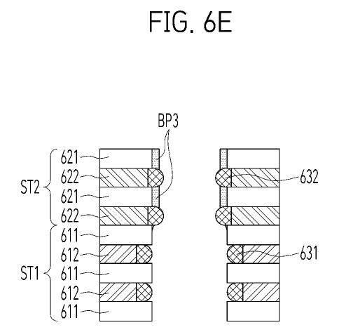

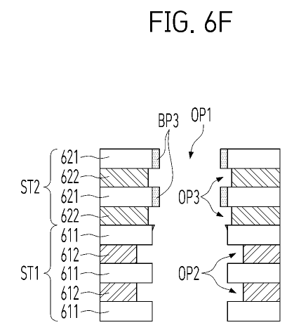

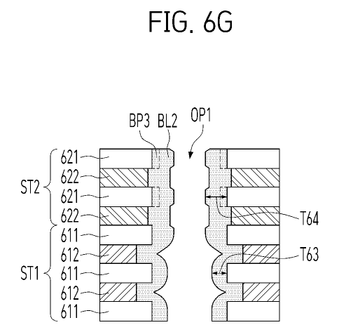

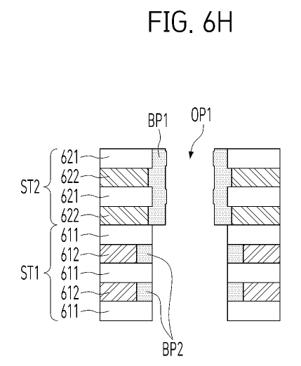

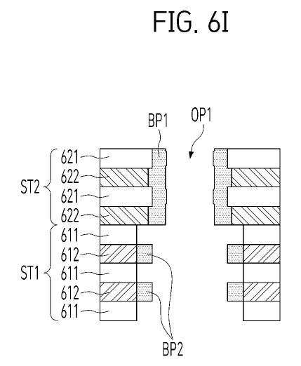

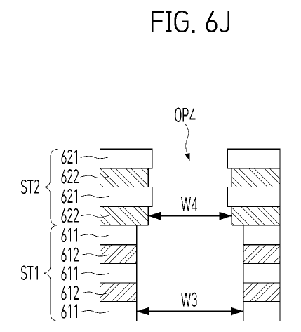

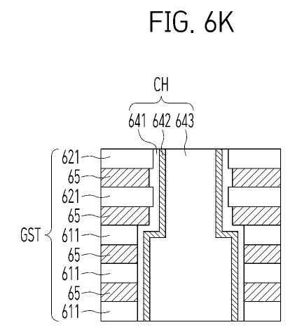

FIGS. 6A to 6K are simplified schematic diagrams describing a method of manufacturing a semiconductor device in accordance with an embodiment of the present disclosure. Hereinafter, content overlapping with previously described content may be omitted.

Referring to FIG. 6A, a first stack ST1 including first insulating layers 611 and first sacrificial layers 612 that are alternately stacked may be formed. Subsequently, a second stack ST2 may be formed on the first stack ST1. The second stack ST2 may include second insulating layers 621 and second sacrificial layers 622 that are alternately stacked.

The first sacrificial layers 612 may each have a first etch rate, and the second sacrificial layers 622 may each have a second etch rate different from the first etch rate. The second etch rate may be lower than the first etch rate. For example, a difference in etch rate between the first sacrificial layers 612 and the second sacrificial layers 622 may be due to a difference in density between the first sacrificial layers 612 and the second sacrificial layers 622. The first sacrificial layers 612 may each have a first density, and the second sacrificial layers 622 may each have a second density different from the first density. The first density may be lower than the second density.

Referring to FIG. 6B, a first opening OP1 extending through the first stack ST1 and the second stack ST2 may be formed. Subsequently, second openings OP2 may be formed by etching the first sacrificial layers 612 through the first opening OP1. The second openings OP2 may be connected to the first opening OP1, and may surround the first opening OP1. The third openings OP3 may be formed by etching the second sacrificial layers 622 through the first opening OP1. The third openings OP3 may be connected to the first opening OP1, and may surround the first opening OP1.

When the second openings OP2 are formed, the third openings OP3 may be formed. However, shapes of the second openings OP2 and the third openings OP3 may be different from each other due to the difference in the etch rate between the first sacrificial layers 612 and the second sacrificial layers 622. An etching speed of the first sacrificial layers 612 may be higher (or faster) than that of the second sacrificial layers 622, and a first width W1 of the second openings OP2 may be greater than a second width W2 of the third openings OP3.

Referring to FIG. 6C, third sacrificial layers 631 may be formed on the first sacrificial layers 612 exposed through the second openings OP2. Fourth sacrificial layers 632 may be formed on the second sacrificial layers 622 exposed through the third openings OP3. The fourth sacrificial layers 632 may protrude into the first opening OP1 compared to the third sacrificial layers 631. For example, the third and fourth sacrificial layers 631 and 632 may each include SiOC.

The third and fourth sacrificial layers 631 and 632 may be selectively deposited on surfaces of the first and second sacrificial layers 612 and 622, respectively. For example, surfaces of the first and second insulating layers 611 and 621 may each include hydroxyl groups, and the surfaces of the first and second sacrificial layers 612 and 622 may include amine groups. Before the third and fourth sacrificial layers 631 and 632 are deposited, inhibitors may be formed on the first and second insulating layers 611 and 621 using precursors adsorbed only on the hydroxyl groups. The inhibitors may inhibit the third and fourth sacrificial layers 631 and 632 from being deposited on the surfaces of the first and second insulating layers 611 and 621. Accordingly, the third and fourth sacrificial layers 631 and 632 may be selectively deposited on the surfaces of the first and second sacrificial layers 612 and 622, respectively.

Referring to FIG. 6D, a first barrier layer BL1 may be formed in the first opening OP1. The first barrier layer BL1 may be formed along the surfaces of the first and second insulating layers 611 and 621 and the third and fourth sacrificial layers 631 and 632. The first barrier layer BL1 may include a material having a high etching selectivity with respect to the third and fourth sacrificial layers 631 and 632. For example, the first barrier layer BL1 may include polysilicon.

A first thickness T61 of the first barrier layer BL1 formed on sidewalls of the first insulating layers 611 may be different from a second thickness T62 of the first barrier layer BL1 formed on sidewalls of the second insulating layers 621. Because the fourth sacrificial layers 632 protrude into the first opening OP1 compared to the third sacrificial layers 631 and the first barrier layer BL1 is formed on the fourth sacrificial layers 632, the second thickness T62 may be greater (or thicker) than the first thickness T61.

Referring to FIG. 6E, third barrier patterns BP3 may be formed between the fourth sacrificial layers 632 by etching the first barrier layer BL1. The third barrier patterns BP3 may be formed on the sidewalls of the second insulating layers 622 exposed between the fourth sacrificial layers 632.

Referring to FIG. 6F, the third and fourth sacrificial layers 631 and 632 may be removed in the first opening OP1. The third and fourth sacrificial layers 631 and 632 may be selectively etched with respect to the first insulating layer 611 and the first and second sacrificial layers 612 and 622. Through this, the first insulating layers 611 and the first and second sacrificial layers 612 and 622 may be exposed in the first opening OP1, and the second and third openings OP2 and OP3 may be reopened.

Referring to FIG. 6G, a second barrier layer BL2 may be formed in the first opening OP1, the second openings OP2, and the third openings OP3 The second barrier layer BL2 may be formed along surfaces of the third barrier patterns BP3, the first insulating layers 611, and the first and second sacrificial layers 612 and 622. The second barrier layer BL2 may include a material having a high etching selectivity with respect to the first insulating layers 611 and the second insulating layers 621. For example, the second barrier layer BL2 may include the same material as the third barrier patterns BP3, and may include polysilicon.

A third thickness T63 of the second barrier layer BL2 formed on the sidewalls of the first insulating layers 611 may be different from a fourth thickness T64 of the second barrier layer BL2 formed on the sidewalls of the second insulating layers 621. Because the second barrier layer BL2 is formed on the third barrier patterns BP3, the fourth thickness T64 may be greater (or thicker) than the third thickness T63.

Referring to FIG. 6H, a first barrier pattern BP1 covering the second stack ST2 may be formed in the first opening OP1 by etching the second barrier layer BL2. The second barrier layer BL2 and the third barrier patterns BP3 remaining after an etching process may be used as the first barrier pattern BP1. Because the fourth thickness T64 is greater (or thicker) than the third thickness T63, the first barrier pattern BP1 may be formed in a spacer shape along sidewalls of the second stack ST2. In addition, second barrier patterns BP2 covering the first sacrificial layers 612 may be formed in the second openings OP2 by etching the second barrier layer BL2. The second barrier patterns BP2 may be formed in the second openings OP2, and may be separated from each other. Sidewalls of the second barrier patterns BP2 may be aligned with the sidewalls of the first insulating layers 611. The first barrier pattern BP1 and the second barrier patterns BP2 may be simultaneously formed by etching the second barrier layer BL2. Through this, the first insulating layers 611 may be exposed in the first opening OP1.

Referring to FIG. 6I, the first insulating layers 611 exposed in the first opening OP1 may be etched using the first barrier pattern BP1 and the second barrier patterns BP2 as etching barriers. In this case, the first insulating layers 611 may be etched so that the sidewalls of the first insulating layers 611 are aligned with sidewalls of the first sacrificial layers 612. The second barrier patterns BP2 may protrude toward the first opening OP1 compared to the first insulating layers 611 and the first sacrificial layers 612.

Referring to FIG. 6J, the first barrier pattern BP1 and the second barrier patterns BP2 may be removed through the first opening OP1. A fourth opening OP4 may be formed by selectively etching the first and second barrier patterns BP1 and BP2 under the condition that etching selectivities of the first and second barrier patterns BP1 and BP2 with respect to the first and second stacks ST1 and ST2 are high. Within the fourth opening OP4, a third width W3 corresponding to the lowermost portion of the first stack ST1 may be greater than a fourth width W4 corresponding to the lowermost portion of the second stack ST2.

Referring to FIG. 6K, a channel structure CH may be formed in the fourth opening OP4. A memory layer 641, a channel layer 642, and an insulating core 643 may be formed in the fourth opening OP4. Subsequently, the first sacrificial layers 612 and the second sacrificial layers 622 may be replaced with conductive layers 65. Through this, a gate structure GST including the conductive layers 65 and the first insulating layers 611 that are alternately stacked and the conductive layers 65 and the second insulating layers 621 that are alternately stacked may be formed. For example, the conductive layers 65 may each include a conductive material such as, for example, polysilicon tungsten (W), or molybdenum (Mo).

According to the method described above, the third barrier patterns BP3 may be formed using the third and fourth sacrificial layers 631 and 632. Through this, the second barrier layer BL2 whose upper and lower portions have different thicknesses may be formed, and the first and second barrier patterns BP1 and BP2 may be formed by etching the second barrier layer BL2. The fourth opening OP4 whose bottom width is expanded may be formed using the first and second barrier patterns BP1 and BP2 as etching barriers. In addition, the channel structure CH whose bottom width is expanded may be formed in the fourth opening OP4. Accordingly, a channel width of a source select transistor may be increased, and a cell current may be improved.

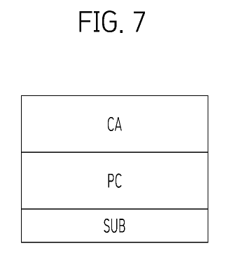

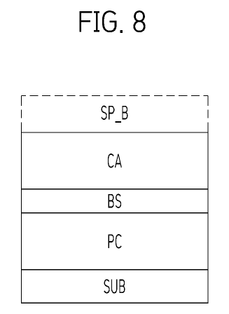

The structures and the methods in accordance with the above-described embodiments may be applied to semiconductor devices having various structures. FIGS. 7 and 8 illustrate schematic configurations of semiconductor devices to which the above-described embodiments are applicable.

FIG. 7 is a configuration diagram of a semiconductor device in accordance with an embodiment of the present disclosure.

Referring to FIG. 7, the semiconductor device may include a substrate SUB, a peripheral circuit PC, and a memory cell array CA. Here, the peripheral circuit PC and the memory cell array CA may be formed on the same substrate.

The substrate SUB may include a semiconductor material. For example, the semiconductor material may include at least one of a group IV semiconductor, a group III-V compound semiconductor, and a group II-VI compound semiconductor. Here, the group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. For example, the substrate SUB may include graphene.

The substrate SUB may be a bulk wafer or an epitaxial layer grown by a selective epitaxial growth (SEG) method. The substrate SUB may be a layer formed by a metal induced lateral crystallization (MILC) method, and may partially include metal. The substrate SUB may have a single crystalline, polycrystalline, or amorphous state. The substrate SUB may include group II, group III, group IV, group V, or group VI impurities. For example, the substrate SUB may include an n-well region doped with n-type impurities and/or a p-well region doped with p-type impurities.

The peripheral circuit PC may be located between the substrate SUB and the memory cell array CA. The peripheral circuit PC may include a row decoder, a column decoder, a page buffer, a logic circuit, a control circuit, a sense amplifier, an input/output circuit, and the like. For example, the peripheral circuit PC may include an N-channel metal oxide semiconductor (NMOS) transistor, a P-channel metal oxide semiconductor (PMOS) transistor, a resistor, a capacitor, and the like. The peripheral circuit PC may further include an interconnection structure. The interconnection structure may be used as a path for transmitting an operation voltage, and may include a contact plug, a wiring line, and the like.

The memory cell array CA may include memory cells. For example, the memory cell array CA may include memory strings connected between a source line and a bit line, and each memory string may include stacked memory cells. For example, the memory cell array CA may include memory cells connected between a word line and the bit line. The memory cell array CA may further include an interconnection structure.

FIG. 8 is a configuration diagram of a semiconductor device in accordance with an embodiment of the present disclosure.

Referring to FIG. 8, the semiconductor device may include a substrate SUB, a peripheral circuit PC, a bonding structure BS, and a memory cell array CA. Here, the peripheral circuit PC and the memory cell array CA may be formed on separate substrates, respectively, and then bonded to each other. The semiconductor device may further include a support base SP_B.

The substrate SUB may be used as a support in a process of forming the peripheral circuit PC. The support base SP_B may be used as a support in a process of forming the memory cell array CA. For example, a first wafer including the memory cell array CA and a second wafer including the peripheral circuit PC may be manufactured, respectively, and then electrically connected to each other by the bonding structure BS. After the first wafer and the second wafer are bonded to each other, the support base SP_B of the first wafer may be at least partially removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown by a selective epitaxial growth (SEG) method, or a layer formed by a metal induced lateral crystallization (MILC) method. The support base SP_B may have a single crystalline, polycrystalline, or amorphous state. The support base SP_B may include group II, group III, group IV, group V, or group VI impurities.

The bonding structure BS may be used to connect the memory cell array CA and the peripheral circuit PC to each other. For example, the bonding structure BS may bond the memory cell array CA and the peripheral circuit PC to each other by a wafer-on-wafer bonding method, a chip-on-wafer bonding method, a chip-on-chip bonding method, or the like. The bonding structure BS may include a bonding pad, a bonding layer, a bonding interface, and the like. The bonding pad may include metal such as copper or aluminum and/or alloys thereof. The bonding interface may include a nonmetal-nonmetal interface, a metal-metal interface, or the like. The memory cell array CA and the peripheral circuit PC may be electrically connected to each other by the bonding structure BS.

For reference, it is also possible for interconnection structures included in the memory cell array CA and/or the peripheral circuit PC to be directly connected to each other without a bonding pad. For example, a bonding layer included in the memory cell array CA and a bonding layer included in the peripheral circuit PC may be bonded to each other to form a bonding interface, and an interconnection structure included in the memory cell array CA and an interconnection structure included the peripheral circuit PC may be directly connected to each other. Through this, contact plugs, wiring lines, and the like, formed on different wafers may be electrically connected to each other without a separate bonding pad.

Other configurations may be the same as or similar to those described above with reference to FIG. 7.

It is also possible for the semiconductor device to have a structure in which embodiments described above with reference to FIGS. 7 and 8 are combined with each other or have a partially modified structure. In embodiments described with reference to FIGS. 7 and 8, locations of the memory cell array CA and the peripheral circuit PC may be changed. At least one memory cell array CA and/or at least one peripheral circuit PC may be additionally bonded in embodiments described with reference to FIGS. 7 and 8. For example, a portion of the peripheral circuit PC may be located in the memory cell array CA. Furthermore, the embodiments may be combined to form additional embodiments.

What is claimed is:

1. A method of manufacturing a semiconductor device, the method comprising:
forming a first stack including first insulating layers and first sacrificial layers that are alternately stacked, each of the first sacrificial layers having a first etch rate;
forming a second stack on the first stack, the second stack including second insulating layers and second sacrificial layers that are alternately stacked, each of the second sacrificial layers having a second etch rate lower than the first etch rate;
forming a first opening extending through the first stack and the second stack;
forming second openings by etching the first sacrificial layers through the first opening, the second openings being connected to the first opening;
forming a first barrier pattern in the first opening, the first barrier pattern covering the second stack;
forming second barrier patterns in the second openings, the second barrier patterns covering the first sacrificial layers; and
etching the first insulating layers using the first barrier pattern and the second barrier patterns as etching barriers.

2. The method of claim 1, further comprising forming third openings by etching the second sacrificial layers through the first opening, the third openings being connected to the first opening.

3. The method of claim 2, wherein the third openings are formed when the second openings are formed.

4. The method of claim 2, wherein a width of each of the second openings is greater than a width of each of the third openings.

5. The method of claim 2, further comprising:
forming third sacrificial layers on the first sacrificial layers exposed through the second openings; and
forming fourth sacrificial layers on the second sacrificial layers exposed through the third openings.

6. The method of claim 5, wherein the third sacrificial layers and the fourth sacrificial layers are formed by a selective deposition method.

7. The method of claim 5, further comprising forming third barrier patterns on the second insulating layers exposed between the fourth sacrificial layers.

8. The method of claim 7, wherein the forming of the third barrier patterns comprises:
forming a first barrier layer along surfaces of the third sacrificial layers, the fourth sacrificial layers, the first insulating layers, and the second insulating layers; and
forming the third barrier patterns by etching the first barrier layer.

9. The method of claim 7, further comprising removing the third sacrificial layers and the fourth sacrificial layers after forming the third barrier patterns.

10. The method of claim 7, further comprising forming a second barrier layer along surfaces of the first stack, the second stack, and the third barrier patterns, in the first opening and the second openings.

11. The method of claim 10, wherein the first barrier pattern and the second barrier patterns are formed by etching the second barrier layer.

12. The method of claim 1, further comprising:
forming a fourth opening by removing the first barrier pattern and the second barrier patterns, the fourth opening having a bottom width greater than a top width; and
forming a channel structure in the fourth opening.

13. A method of manufacturing a semiconductor device, the method comprising:
forming a first stack including first insulating layers and first sacrificial layers that are alternately stacked;
forming a second stack on the first stack, the second stack including second insulating layers and second sacrificial layers that are alternately stacked;
forming a first opening extending through the first stack and the second stack;
forming second openings by etching the first sacrificial layers through the first opening, the second openings being connected to the first opening;
forming a barrier layer along surfaces of the first stack and the second stack exposed through the first opening and the second openings, the barrier layer having a first thickness on the first insulating layers and a second thickness on the second insulating layers wherein the second thickness is greater than the first thickness;
forming a first barrier pattern by etching the barrier layer, the first barrier pattern covering the second stack;
forming second barrier patterns in the second openings by etching the barrier layer; and
etching the first insulating layers using the first barrier pattern and the second barrier patterns as etching barriers.

14. The method of claim 13, where in the forming of the second openings, an etch rate of the first sacrificial layers is higher than an etch rate of the second sacrificial layers.

15. The method of claim 13, wherein the forming of the barrier layer comprises:
forming third barrier patterns on the second insulating layers exposed through the first opening; and
forming the barrier layer covering the third barrier patterns.

16. The method of claim 13, further comprising forming third openings by etching the second sacrificial layers through the first opening, the third openings being connected to the first opening.

17. The method of claim 16, wherein the forming of the third barrier patterns comprises:
forming third sacrificial layers on the first sacrificial layers exposed through the second openings;
forming fourth sacrificial layers on the second sacrificial layers exposed through the third openings;
forming a first barrier layer in the first opening, the first barrier layer covering the third sacrificial layers, the fourth sacrificial layers, the first insulating layers, and the second insulating layers; and
forming the third barrier patterns on sidewalls of the second insulating layers exposed between the fourth sacrificial layers by etching the first barrier layer.

18. The method of claim 17, wherein the third sacrificial layers and the fourth sacrificial layers are formed by a selective deposition method.

19. The method of claim 17, further comprising removing the third sacrificial layers and the fourth sacrificial layers after forming the third barrier patterns.

20. The method of claim 13, further comprising:
forming a fourth opening by removing the first barrier pattern and the second barrier patterns, the fourth opening having a bottom width greater than a top width; and
forming a channel structure in the fourth opening.
